(19) United States
(12) Patent Application Publication
(10) Pub. No.: US 2024/0186126 A1
(43) Pub. Date: Jun. 6, 2024

(54) MONITORING SYSTEM, APPARATUS, AND METHOD FOR DETERMINING MAINTENANCE CYCLE OF PROCESSING CHAMBER

(71) Applicant: RESEARCH & BUSINESS FOUNDATION SUNGKYUNKWAN UNIVERSITY, Suwon-si (KR)

(72) Inventors: Geun Young YEOM, Seoul (KR); Dong Woo KIM, Seoul (KR); Ji Eun KANG, Yongin-si (KR); Seung Yup CHOI, Pyeongtaek-si (KR)

(73) Assignee: RESEARCH & BUSINESS FOUNDATION SUNGKYUNKWAN UNIVERSITY, Suwon-si (KR)

(21) Appl. No.: 18/527,416

(22) Filed: Dec. 4, 2023

(30) Foreign Application Priority Data
Dec. 5, 2022 (KR) 10-2022-0167950

(51) Int. Cl. H01J 37/32; G01N 29/036; G01N 29/24; G01N 29/46

(52) U.S. Cl. CPC H01J 37/32935; G01N 29/036; G01N 29/2437; G01N 29/46; H01J 37/32862; G01N 2291/021; G01N 2291/02809; H01J 2237/244; H01J 2237/24578

(57) ABSTRACT

Proposed is a system for monitoring internal conditions of a processing chamber. The system includes at least one sensor provided inside the processing chamber and configured to measure an amount of reactant present inside the processing chamber, and a monitoring apparatus configured to monitor the internal conditions of the processing chamber on the basis of a measurement value received from the at least one sensor, wherein the monitoring apparatus determines at least one of a start point and an end point of a cleaning process for the processing chamber on the basis of a change in the measurement value.

### CROSS REFERENCE TO RELATED APPLICATION

The present application claims priority to Korean Patent Application No. 10-2022-0167950, filed on Dec. 5, 2022, the entire contents of which is herein incorporated by reference.

### BACKGROUND OF THE INVENTION

### Field of the Invention

The present disclosure relates to a system, apparatus, and method for monitoring internal conditions of a processing chamber used in semiconductor processing and, more particularly, to a system, apparatus, and method for monitoring the internal conditions of the processing chamber to determine preventive maintenance intervals for the processing chamber.

### Description of the Related Art

Due to device miniaturization in semiconductor manufacturing, the development of precision/microstructure etching processes such as atomic layer etching is becoming very important. Accordingly, the importance of a cleaning process for contamination and particle management of related equipment is also greatly increasing.

Cleaning is the process of removing foreign substances from the inner wall of a processing chamber or the surface of a wafer. If cleaning does not proceed perfectly, foreign substances remaining inside a processing chamber will affect the next process. On the other hand, if cleaning is performed excessively, the inner wall of a processing chamber is damaged and the overall processing time also increases. As such, although a cleaning process plays an essential role in the semiconductor manufacturing, real-time and/or quantitative monitoring of the cleaning process is not implemented, and consequently the impact of the cleaning process on micro-etching and deposition processes may not be confirmed.

Meanwhile, there is a method using an optical sensor as a way to monitor a plasma process. However, because the optical sensor uses light, the accuracy of monitoring is reduced due to interference by plasma in a processing chamber. Moreover, in addition to optical sensors, sensors mounted inside a chamber are installed in a bulk form within a processing chamber, and thus the uniformity of plasma is disrupted, which reduces the reproducibility of a plasma process.

### Documents of Related Art

(Patent Document 0001) Korean Patent No. 10-2200152 (registered Jan. 4, 2021)

### SUMMARY OF THE INVENTION

Accordingly, the present disclosure has been made keeping in mind the above problems occurring in the related art, and an objective of the present disclosure is to provide a system, apparatus, and method for monitoring in real time the amounts of reactants produced and/or removed within a processing chamber during a semiconductor manufacturing process.

An objective of the present disclosure is to provide a system, apparatus, and method for monitoring internal conditions of a processing chamber without affecting plasma during a semiconductor manufacturing process.

An objective of the present disclosure is to provide a system, apparatus, and method for accurately determining preventive maintenance intervals for a processing chamber.

The objectives to be achieved by the present disclosure are not limited to those mentioned above, and other objectives not mentioned may be clearly understood by those skilled in the art from the following description.

In order to accomplish the above objectives, according to an embodiment of the present disclosure, there is provided a system for monitoring internal conditions of a processing chamber, the system including: at least one sensor provided inside the processing chamber and configured to measure an amount of reactant present inside the processing chamber; and a monitoring apparatus configured to monitor the internal conditions of the processing chamber on the basis of a measurement value received from the at least one sensor, wherein the monitoring apparatus may determine at least one of a start point and an end point of a cleaning process for the processing chamber on the basis of a change in the measurement value.

In this case, the at least one sensor is a thin film-type sensor including: a sensing module including a pair of substrates, a pair of electrodes provided between the pair of substrates, and a piezoelectric element provided between the pair of electrodes; and a wireless communication module configured to transmit a measurement value measured by the sensing module to the monitoring apparatus through a wireless communication network.

In addition, the measurement value may include a frequency value for vibration generated by the piezoelectric element, and the monitoring apparatus may monitor an amount of reactant present inside the processing chamber on the basis of a change in the frequency value.

In addition, the monitoring apparatus may determine the start point of the cleaning process on the basis of the measurement value reaching a threshold value.

In addition, the threshold value may be set on the basis of at least one of a type of gas discharged inside the processing chamber, a component ratio of the gas, an internal pressure of the processing chamber, and power applied to the processing chamber.

In addition, the monitoring apparatus may determine the end point of the cleaning process on the basis of the change in the measurement value within a preset range after the start point of the cleaning process.

In addition, the monitoring apparatus may determine the end point of the cleaning process on the basis of the measurement value being within the preset range for a preset period of time after the start point of the cleaning process.

In addition, the at least one sensor may include a plurality of sensors, wherein the plurality of sensors may be provided at different locations inside the processing chamber, and the monitoring apparatus may determine the start point of the cleaning process on the basis of whether at least one of measurement values measured by the plurality of sensors is below a preset threshold value, and may determine the end point of the cleaning process on the basis of the measurement values measured by the plurality of sensors changing within a preset range.

According to another embodiment of the present disclosure, an apparatus for monitoring internal conditions of a processing chamber may include: a communication module configured to receive a measurement value from at least one sensor provided inside the processing chamber; and a processor configured to monitor the internal conditions of the processing chamber on the basis of the measurement value and to determine at least one of a start point and an end point of a cleaning process for the processing chamber on the basis of a change in the measurement value.

According to still another embodiment of the present disclosure, an apparatus for measuring internal conditions of a processing chamber may include: a sensing module including a pair of substrates, a pair of electrodes provided between the pair of substrates, and a piezoelectric element provided between the pair of electrodes; and a wireless communication module configured to transmit a measurement value measured by the sensing module through a wireless communication network.

According to still another embodiment of the present disclosure, a monitoring method performed by an apparatus that monitors internal conditions of a processing chamber may include: receiving a measurement value from at least one sensor provided inside the processing chamber; monitoring the internal conditions of the processing chamber on the basis of the measurement value; and determining at least one of a start point and an end point of a cleaning process for the processing chamber on the basis of a change in the measurement value.

According to still another embodiment of the present disclosure, a computer program stored on a computer-readable recording medium may include: instructions, when executed by a processor, for prompting the processor to perform a processing chamber monitoring method including: monitoring internal conditions of a processing chamber on the basis of a measurement value received from at least one sensor provided inside the processing chamber; and determining at least one of a start point and an end point of a cleaning process for the processing chamber on the basis of a change in the measurement value.

According to still another embodiment of the present disclosure, a computer-readable recording medium that stores a computer program may include: instructions, when executed by a processor, for prompting the processor to perform a processing chamber monitoring method including: monitoring internal conditions of a processing chamber on the basis of a measurement value received from at least one sensor provided inside the processing chamber; and determining at least one of a start point and an end point of a cleaning process for the processing chamber on the basis of a change in the measurement value.

According to an embodiment of the present disclosure, since internal conditions of a processing chamber can be monitored in real time, start and end points of a cleaning process can be accurately determined in real time.

According to an embodiment of the present disclosure, by checking a preventive maintenance cycle of a processing chamber, time loss can be reduced and productivity can be increased in a semiconductor manufacturing system.

According to an embodiment of the present disclosure, since internal conditions of a processing chamber is monitored using a thin film sensor provided inside the processing chamber, process reproducibility is not affected.

According to an embodiment of the present disclosure, since it is possible to accurately determine when a cleaning process ends, greenhouse gases used in the cleaning process can be reduced, thereby contributing to carbon neutrality.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view showing a system for monitoring internal conditions of a processing chamber according to an embodiment of the present disclosure;

FIG. 2 is a view showing a processing chamber equipped with a sensor according to an embodiment of the present disclosure;

FIG. 3 is a view showing a sensor according to an embodiment of the present disclosure;

FIG. 4 is a view showing a monitoring apparatus according to an embodiment of the present disclosure;

FIG. 5 is a view showing the amount of reactant deposited inside a processing chamber depending on power applied to the processing chamber;

FIG. 6 is a view showing the amount of reactant deposited inside a processing chamber depending on pressure of gas in the processing chamber;

FIG. 7 is a view showing the amount of reactant deposited inside a processing chamber depending on component ratio of gas discharged inside the processing chamber;

FIG. 8 is a view showing the completion time of a cleaning process depending on power applied to a processing chamber;

FIG. 9 is a view showing the completion time of a cleaning process depending on type of cleaning gas;

FIG. 10 is a view showing a method for monitoring internal conditions of a processing chamber according to an embodiment of the present disclosure;

FIG. 11 is a view showing a method for determining the end point of a cleaning process according to an embodiment of the present disclosure;

FIG. 12 is a view showing the amount of reactant deposited inside a processing chamber;

FIG. 13 is a view showing the amount of reactant deposited inside a processing chamber for each measurement location inside the processing chamber;

FIG. 14 is a view showing the amount of reactant removed by a cleaning process inside a processing chamber;

FIG. 15 is a view showing the amount of reactant removed inside a processing chamber for each measurement location inside the processing chamber; and

FIG. 16 is a view showing comparing the amount of reactant removed inside a processing chamber with other analysis devices.

### DETAILED DESCRIPTION OF THE INVENTION

The advantages and features of the present disclosure, and methods of achieving them, will become clear with reference to the embodiments described below in conjunction with the accompanying drawings. However, the present disclosure is not limited to the embodiments disclosed below, but may be implemented in various different forms. The embodiments are provided solely to ensure that the disclosure of the present disclosure is complete and to fully inform those skilled in the art of the scope of the invention. The present disclosure is defined only by the scope of the claims.

The terms used in this document will be briefly explained, and the present disclosure will be described in detail.

The terms used in the present disclosure are general terms that are currently widely used as much as possible while considering the function in the present disclosure, but this may vary depending on the intention or precedent of a person working in the art, the emergence of new technology, etc. In addition, in certain cases, there are terms arbitrarily selected by the applicant, and in this case, the meaning will be described in detail in the relevant description of the present disclosure. Therefore, the terms used in the present disclosure should be defined based on the meaning of the term and the overall content of the present disclosure, rather than simply the name of the term.

Throughout the specification, when a part is said to “comprise (include)” a certain component, this means that the part does not exclude other components, but may include other components, unless specifically stated to the contrary.

In addition, the term “part” used on this document refers to software or hardware components such as FPGA or ASIC, and “part” performs certain roles. However, “part” is not limited to software or hardware. The “part” may be configured to reside on an addressable storage medium and may be configured to reproduce on one or more processors. Thus, as an example, includes components such as software components, object-oriented software components, class components and task components, processes, functions, properties, procedures, subroutines, segments of program code, drivers, firmware, microcode, circuits, data, databases, data structures, tables, arrays, and variables. The functionality provided within components and parts may be combined into a smaller number of components and parts or further separated into additional components and parts.

Hereinafter, with reference to the attached drawings, embodiments of the present disclosure will be described in detail so that those skilled in the art can easily implement the present disclosure.

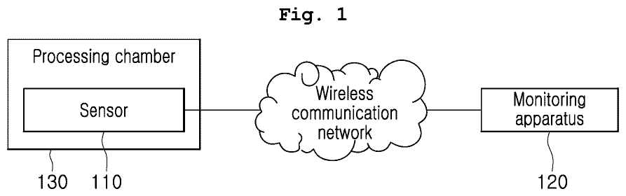

FIG. 1 is a view showing a system for monitoring internal conditions of a processing chamber according to an embodiment of the present disclosure.

Referring to FIG. 1, a processing chamber monitoring system according to an embodiment of the present disclosure includes at least one sensor 110 and a monitoring apparatus 120.

The sensor 110 is configured to measure and/or detect internal conditions of a processing chamber 130, which change due to exposure to plasma during a semiconductor manufacturing process (etching, deposition, etc.). In an embodiment, the internal conditions of the processing chamber 130 may relate to an amount of reactants accumulated inside the processing chamber 130 by repeated use in the semiconductor manufacturing process. The sensor 110 may measure and/or sense the internal conditions of the processing chamber 130 even during a cleaning process. For this purpose, the sensor 110 may be provided inside the processing chamber 130 (e.g., inner wall, substrate, etc.). Although in FIG. 1, one sensor 110 is shown as being included inside the processing chamber 130 as an example, a plurality of sensors may be provided at different positions and/or heights within the processing chamber 130.

As an example, the sensor 110 may measure and/or sense the amounts of reactants present inside the processing chamber 130 in real time and transmit the measured and/or sensed information to the monitoring apparatus 120 through a wireless communication network, and in this case, the reactants may include byproducts generated by a process reaction, such as polymers. To this end, the sensor 110 may include: a sensing module containing a material having a piezo effect (hereinafter referred to as a “piezoelectric element”); and a wireless communication module for transmitting a measurement value of the sensing module to the outside through the wireless communication network.

The monitoring apparatus 120 is configured to monitor the internal conditions of the processing chamber 130 on the basis of the measurement value received from the sensor 110. The monitoring apparatus 120 may determine the start point and/or end point of the cleaning process for the processing chamber 130 on the basis of the change and/or amount of change in the measurement value measured by the sensor 110. As an example, the monitoring apparatus 120 may monitor the amounts of reactants present inside the processing chamber based on the measurement value of the sensor 110. At this time, the measurement value received from the sensor 110 may include a frequency value for vibration generated by expansion and contraction of the piezoelectric element. In this case, the monitoring apparatus 120 may monitor the amounts of reactants present inside the processing chamber 130 on the basis of the change in the frequency value. For example, the monitoring apparatus 120 may determine and/or determine that the start point of the cleaning process has been reached when the measurement value is below a preset threshold, that is, when the measurement value reaches the threshold. At this time, the threshold may be determined and/or set on the basis of the type of gas discharged inside the processing chamber 130, the component ratio of the gas, the pressure of the gas within the processing chamber 130, the power applied to the processing chamber 130, etc. Meanwhile, after the start of the cleaning process, that is, when the measurement value received from the sensor 110 changes within a preset range for a preset time, that is, when the amount of change in the measurement value is within a predetermined range over a predetermined period of time, or when it is confirmed that the measurement value has reached the cleaning end point, the monitoring apparatus 120 may determine and/or decide that the end point of the cleaning process has been reached.

As an example, when the processing chamber monitoring system includes a plurality of sensors, the plurality of sensors may be provided at different locations within the processing chamber 130. In this case, the monitoring apparatus 120 may determine that it is time to start the cleaning process if at least one of the measurement values measured by the plurality of sensors is less than or equal to a preset threshold. In addition, the monitoring apparatus 120 may determine that the time to end the cleaning process has been reached when the measurement values measured by the plurality of sensors during the cleaning process all change within a preset range.

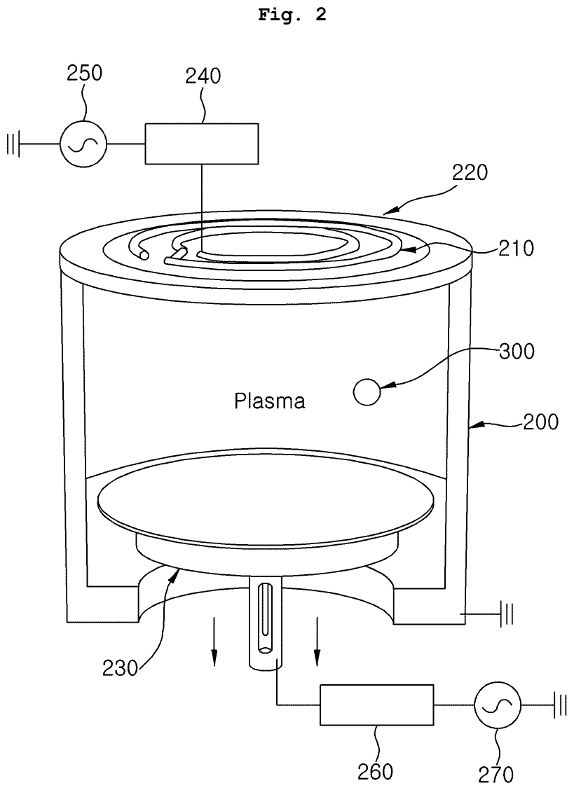

FIG. 2 is a view showing a processing chamber equipped with a sensor according to an embodiment of the present disclosure.

Referring to FIG. 2, a processing chamber 200 may include an inductively coupled plasma (ICP) coil 210, an upper plate 220, and a vacuum pump 230.

The ICP coil 210 is a coil for generating ICP and may be connected to a first matcher 240 and a first radio frequency (RF) oscillator 250. The ICP coil 210 may be replaced with a capacitively coupled plasma (CCP) electrode. Source power generated by the first RF oscillator 250 is applied to the ICP coil 210 after impedance matching is performed by means of the first matcher 240, and within the processing chamber 200, plasma is generated by induced current in the ICP coil 210.

The upper plate 220 is a plate that covers the upper part of the processing chamber 200 and may be composed of, for example, a quartz plate.

The vacuum pump 230 is for depressurizing the processing chamber 200 and may be connected to a second matcher 260 and a second RF oscillator 270. Bias power generated by the second RF oscillator 270 is applied to the vacuum pump 230 after impedance matching is performed by means of the second matcher 260, and due to this, ion energy in the processing chamber 200 may be adjusted. The vacuum pump 230 may be configured as, for example, a turbo molecular pump (TMP).

At this time, a sensor 300 may be, for example, embedded in the inner wall of the processing chamber 200 as shown in FIG. 2. Alternatively, the sensor 300 may be provided under the upper plate 220 in the processing chamber 200 or may be provided on one side of a wafer provided on the vacuum pump 230. When a plurality of sensors is used to monitor the internal conditions of the processing chamber 200, the plurality of sensors may be provided at different locations within the processing chamber 200.

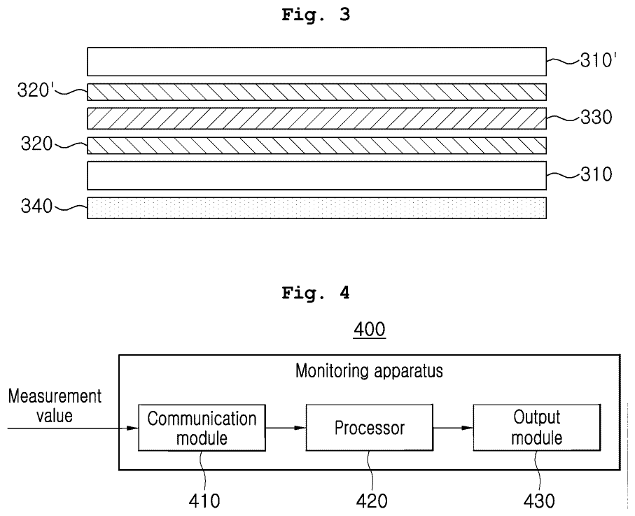

FIG. 3 is a view showing a sensor according to an embodiment of the present disclosure.

A sensor according to an embodiment of the present disclosure may be embedded inside the processing chamber and may be configured as a thin film so as not to affect plasma. In the embodiment of the present disclosure, the sensor may include a sensing module and a wireless communication module.

Referring to FIG. 3, the sensing module includes: a pair of substrates 310 and 310′; a pair of electrodes 320 and 320′ provided between the pair of substrates 310 and 310′; and a piezoelectric element 330 provided between the pair of electrodes 320 and 320′.

Each of the substrates 310 and 310′ may be composed of ceramic materials (SiO₂, Si₃N₄, Al₂O₃, SiC, etc.) and polymer-based materials (polyimide, etc.), and may be coated with an insulator, metals, etc. depending on the type of substrate and the type of process gas. In addition, to remove plasma noise that may affect sensor measurements, individual substrates 310 and 310′ may be processed through a separate passivation process.

Each of the electrodes 320 and 320′ may contain aluminum (Al), nickel (Ni), copper (Cu), gold (Au), chromium (Cr), titanium (Ti), platinum (Pt), tungsten (W), and alloys thereof. The first electrode 320 may be deposited on a thin first substrate 310. The piezoelectric element 330 may be located on the first electrode 320. A second substrate 310′ on which the second electrode 320′ is deposited may be positioned on the piezoelectric element 330.

The piezoelectric element 330 is a material that has a piezo effect, and the thickness thereof may be adjusted depending on the amount of material (compound) to be measured. For example, the more byproducts deposited in the processing chamber, the thicker the piezoelectric element may be manufactured.

The wireless communication module 340 may be provided above or below the sensing module and may be configured to transmit a measurement value generated by the sensing module to a monitoring apparatus through a wireless communication network. At this time, the wireless communication module 340 may transmit the measurement value using a frequency band that is not affected by plasma and/or electromagnetic fields within the processing chamber.

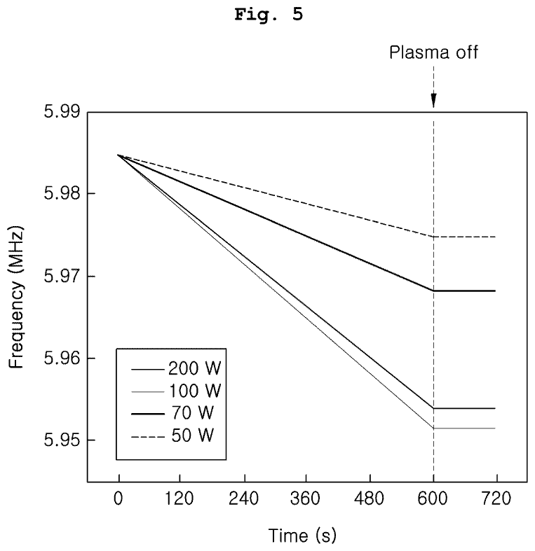

FIG. 4 is a view showing a monitoring apparatus according to an embodiment of the present disclosure.

Referring to FIG. 4, a monitoring apparatus 400 for monitoring internal conditions of a processing chamber may include a communication module 410, a processor 420, and an output module 430.

The communication module 410 may receive a measurement value from at least one sensor provided inside a processing chamber. In this case, the measurement value may include a frequency value for vibration generated by expansion and contraction of a piezoelectric element in a at least one sensor.

The processor 420 may monitor internal conditions of the processing chamber on the basis of the measurement value received from the communication module 410. In addition, the processor 420 may determine at least one of the start and end points of a cleaning process for the corresponding processing chamber on the basis of the change in the measurement value.

For example, the processor 420 may monitor the amounts of reactants present inside the processing chamber on the basis of the change in the frequency value. When the measurement value is less than or equal to a preset threshold, the processor 420 may determine that the start point of the cleaning process for the corresponding processing chamber has been reached. In this case, the threshold may be determined and/or set on the basis of the type of gas discharged inside the corresponding processing chamber, the component ratio of the gas, the pressure of the gas within the corresponding processing chamber, the power applied to the corresponding processing chamber, etc. Meanwhile, after the start of the cleaning process for the corresponding processing chamber, that is, when the measurement value received from the sensor changes within a preset range for a predetermined period of time, or is judged to have reached the cleaning end point, the processor 420 may determine and/or decide that the end point of the cleaning process has been reached.

The output module 430 may output information about the internal conditions of the processing chamber, information about the start point of the cleaning process, information about the end point of the cleaning process, etc. through an external device (display device, user terminal, etc.).

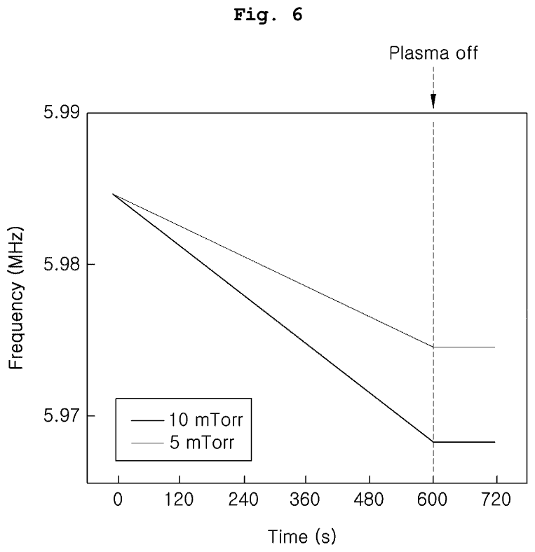

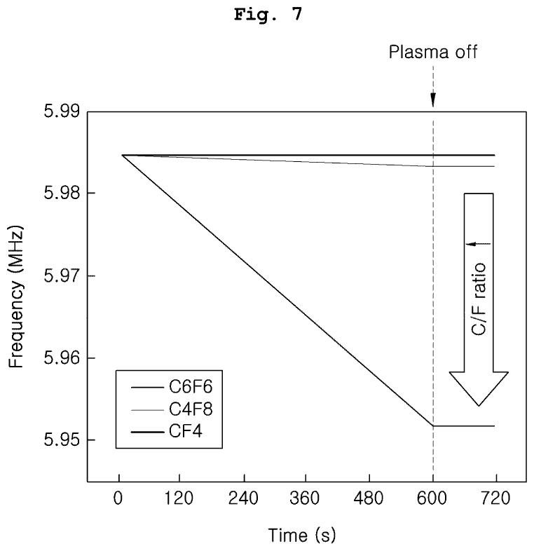

FIG. 5 is a view showing the amount of reactant deposited inside a processing chamber depending on power applied to the processing chamber, and FIG. 6 is a view showing the amount of reactant deposited inside a processing chamber depending on pressure of gas in the processing chamber.

FIGS. 5 and 6 show, as an example, the results of measuring the amount of fluorine compounds accumulated inside the processing chamber. CFₓ-based gas was discharged inside the processing chamber, and the amount of fluorine compounds accumulated inside was compared according to gas pressure and applied power conditions.

Referring to FIGS. 5 and 6, as the gas pressure and applied power increase, the amount of fluorine compounds decomposed increases, and thus a greater amount of fluorine compounds accumulates inside the chamber. This trend is also shown in the sensor measurement results. Therefore, by setting a specific value as the threshold on the basis of the pressure of the gas in the processing chamber and/or the power applied to the processing chamber, it is possible to accurately determine when the cleaning process should proceed in real time and quantitatively.

FIG. 7 is a view showing the amount of reactant deposited inside a processing chamber depending on component ratio of gas discharged inside the processing chamber.

FIG. 7 shows, as an example, the results of measuring the amount of fluorine compounds inside a processing chamber for each C/F ratio of CFₓ. Referring to FIG. 7, as the C/F ratio increases, the amount of C increases, and thus the amounts of C-based compounds accumulating inside the chamber increases. In the actual measurement results, it can be seen that the amounts of compounds accumulating inside the chamber increases in the following order: C₆F₆ (1:1)>C₄F₈ (1:2)>CF₄ (1:4). Therefore, by setting a specific value as the threshold based on the type and/or component ratio of the gas discharged inside the processing chamber, it is possible to accurately determine when the cleaning process should in proceed real time and quantitatively. Thus, the processing chamber monitoring system according to the present disclosure may monitor the internal conditions of a processing chamber regardless of changes in various process variable conditions such as gas type, component ratio, pressure, and power, and may accurately determine when a cleaning process is needed and when the cleaning process is terminated.

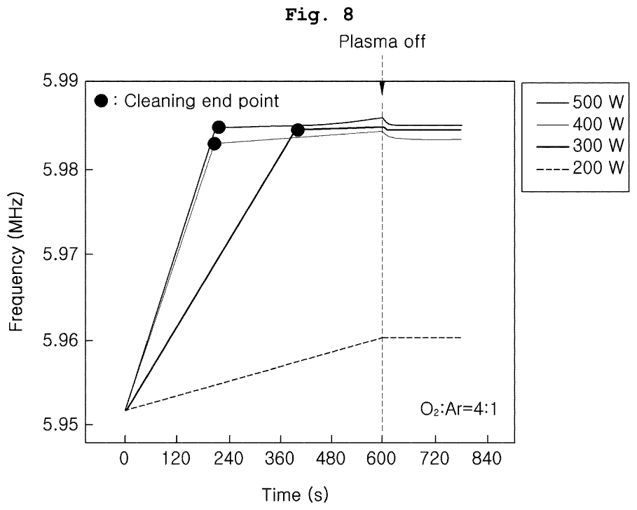

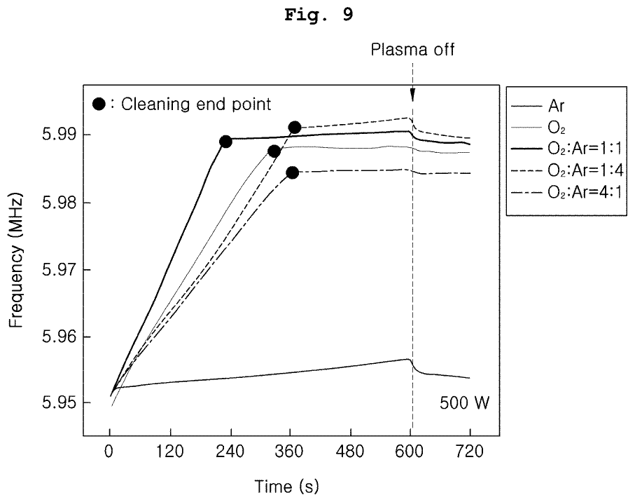

FIG. 8 is a view showing the completion time of a cleaning process depending on power applied to a processing chamber, and FIG. 9 is a view showing the completion time of a cleaning process depending on type of cleaning gas.

FIGS. 8 and 9 show the results of removing fluorine compounds accumulated inside a processing chamber during a cleaning process and measuring this process with a sensor. Referring to FIGS. 8 and 9, once the cleaning process reaches the end point, the sensor's measurement values remain virtually unchanged even if the cleaning process continues. Thus, the processing chamber monitoring system according to the present disclosure may accurately determine when cleaning is complete on the basis of whether the sensor's measurement values reach the cleaning endpoint or change within a certain range after the start of the cleaning process.

In addition, referring to FIGS. 8 and 9, the cleaning process shows that the cleaning effect varies over time depending on the power and gas ratio. In particular, referring to FIG. 9, the cleaning effect according to the O₂:Ar ratio is excellent in the order of 1:1>1:0>4:1>1:4>0:1. Due to this, it is possible to determine not only when the cleaning process is completed, but also the optimal cleaning process combination.

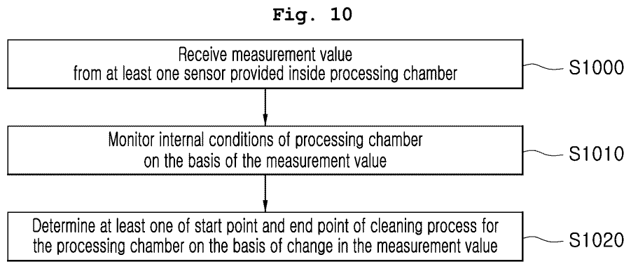

FIG. 10 is a view showing a method for monitoring internal conditions of a processing chamber according to an embodiment of the present disclosure.

Referring to FIG. 10, a monitoring apparatus in a processing chamber monitoring system may receive (S1000) a measurement value from at least one sensor provided inside a processing chamber through a wireless communication network. The monitoring apparatus may monitor (S1010) internal conditions of the processing chamber on the basis of the measurement value. As an example, the measurement value that the monitoring apparatus receives from at least one sensor may be a frequency value for vibration generated by a piezoelectric element in the corresponding sensor, and in this case, the monitoring apparatus may monitor the amounts of reactants present inside the processing chamber on the basis of the change in the frequency value.

In addition, the monitoring apparatus may determine at least one of the start and end points of a cleaning process for the processing chamber based on the change in the measurement value.

For example, as shown in FIGS. 5 to 7, the monitoring apparatus may determine that the start point of the cleaning process has been reached when the measurement value received from at least one sensor is below a preset threshold. To this end, the monitoring apparatus may determine a threshold on the basis of a specific frequency value, and the time taken to reach the threshold may vary depending on the type of gas discharged inside the processing chamber, the component ratio of the gas, the internal pressure of the processing chamber, the power applied to the processing chamber, etc. In addition, as shown in FIGS. 8 and 9, the monitoring apparatus may determine that the end point of the cleaning process has been reached if a measurement value received from at least one sensor after the start point of the cleaning process reaches the cleaning end point.

Thereafter, the monitoring apparatus may output information about the internal conditions of the processing chamber, information about the start point of the cleaning process, information about the end point of the cleaning process, etc.

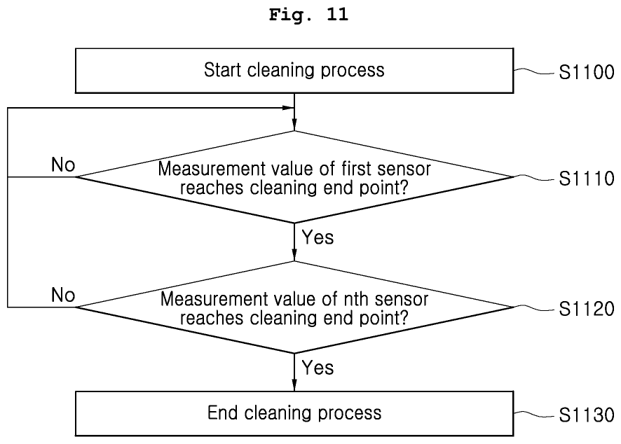

FIG. 11 is a view showing a method for determining the end point of a cleaning process according to an embodiment of the present disclosure.

Hereinafter, with reference to FIG. 11, a case in which a plurality of sensors is provided inside a processing chamber will be described. Referring to FIG. 11, the monitoring apparatus may determine that a cleaning process for a processing chamber has reached the start point if a measurement value of at least one of the plurality f sensors provided inside the processing chamber is below a preset threshold. When the cleaning process for the processing chamber begins (S1100), the monitoring apparatus may determine (S1110) whether a measurement value of a first sensor among the plurality of sensors in the processing chamber has reached the cleaning end point. When the measurement value of the first sensor reaches the cleaning end point, the monitoring apparatus may determine a measurement value of a second sensor has reached the cleaning end point, and when the measurement value of the second sensor reaches the cleaning end point, the monitoring apparatus may determine (S1120) whether a measurement value of a nth sensor has reached the cleaning end point. If necessary, the cleaning process may be terminated after confirming that one or more sensor measurements have reached the cleaning end point. When all measurement values received from the plurality of sensors in the processing chamber reach the cleaning end point, or when the measurement values all change within a predetermined range, the monitoring apparatus may determine (S1130) that the cleaning end point has been reached, and the cleaning process may be terminated at that point.

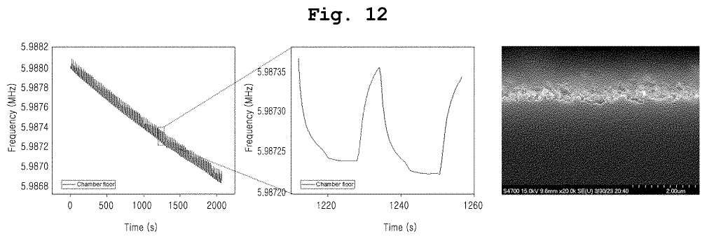

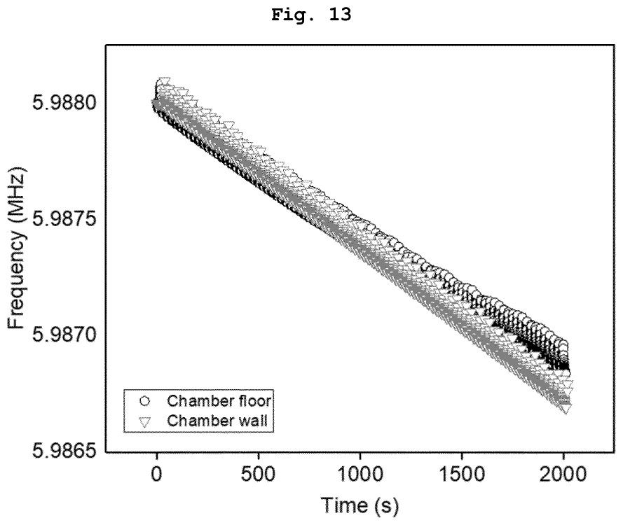

FIG. 12 is a view showing the amount of reactant deposited inside a processing chamber, and FIG. 13 is a view showing the amount of reactant deposited inside a processing chamber for each measurement location inside the processing chamber.

FIGS. 12 and 13 show, as an example, the results of measuring the amount of silicon oxide accumulated inside a processing chamber. After injecting a precursor into the processing chamber, O₂-based gas was discharged, the amount of silicon oxide accumulated inside was measured, and the rate at which the reactants accumulate on the chamber walls and chamber floor was compared.

Referring to FIGS. 12 and 13, since the amount of reactant accumulating increases as the processing time passes, the rate at which reactant is accumulating may be compared through the slope of the measurement value over time, and it can be seen that the rate at which the reactant accumulates on the walls of the chamber is faster than on the floor of the chamber. Thus, the rate at which the reactant accumulates varies depending on the location inside the chamber, and it is possible to compare and analyze these differences according to the measurement location.

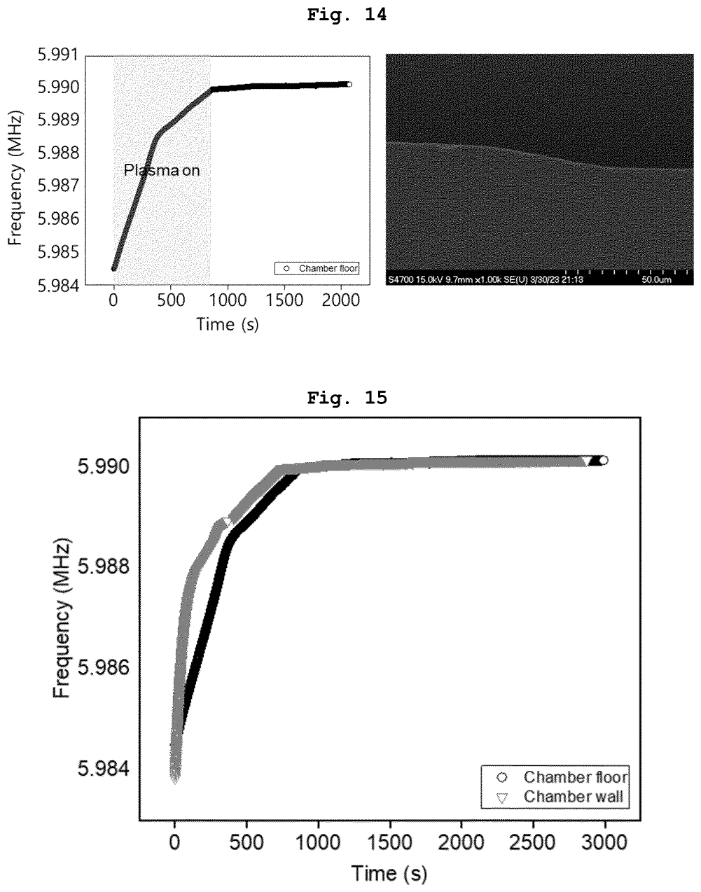

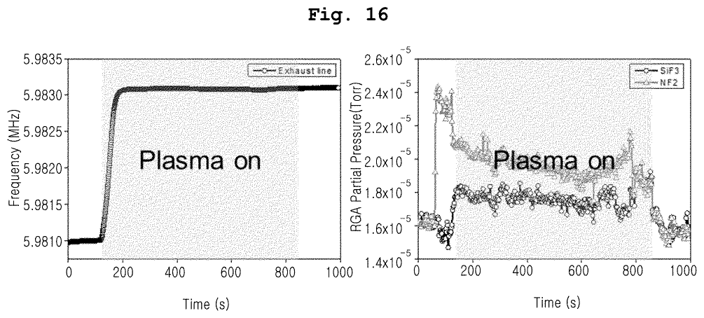

FIG. 14 is a view showing the amount of reactant removed by a cleaning process inside a processing chamber, and FIG. 15 is a view showing the amount of reactant removed inside a processing chamber for each measurement location inside the processing chamber.

FIGS. 14 and 15 show, as an example, the results of measuring the amount of silicon oxide accumulated inside a processing chamber removed as a cleaning process proceeds. NF₃ gas was discharged inside the processing chamber, the amount of silicon oxide accumulated inside was measured, and the rate at which the reactant was removed from the chamber walls and chamber floor was compared.

Referring to FIGS. 14 and 15, by comparing the slope for the reactant removed over time, it can be confirmed that the rate at which the reactant is removed is faster from the walls than the floor of the chamber, and the rate at which the reactant is removed also varies with time. Thus, the rate at which the reactant is removed varies depending on the location inside the chamber or the processing time, and it is possible to compare and analyze these differences according to the measurement location and processing time.

FIG. 16 is a view showing comparing the amount of reactant removed inside a processing chamber with other analysis devices.

FIG. 16 shows the results of removing silicon oxide accumulated inside a processing chamber and in an exhaust line during a cleaning process, and simultaneously measuring this process with a residual gas analyzer and a sensor in the processing chamber exhaust line. Referring to FIG. 16, when measured with the sensor in the exhaust line, it can be confirmed that the sensor's measurement value hardly changes even if the cleaning process continues after reaching the end point of the cleaning process. On the other hand, in the case of the residual gas analyzer, the reactant from the cleaning process is continuously measured during the cleaning process. This is because even if the residual gas analyzer is attached to the exhaust line and measures the reactant, all reactants discharged from inside the processing chamber and discharged from the exhaust line are measured. That is, even if the cleaning end point has been reached in the exhaust line, the cleaning end point of the exhaust line may not be confirmed because the reactant discharged from inside the chamber is measured. Thus, the processing chamber monitoring system according to the present disclosure may accurately determine when cleaning is complete on the basis of whether the sensor's measurement value reaches the cleaning end point or changes within a predetermined range after the start of the cleaning process.

Therefore, the processing chamber monitoring system according to the present disclosure may monitor the internal conditions of the processing chamber regardless of changes in various process variable conditions such as measurement location and time.

Meanwhile, each step included in the processing chamber monitoring method performed by the apparatus for monitoring internal conditions of a processing chamber according to the above-described embodiment may be implemented as a computer program recorded on a recording medium, including instructions to prompt a processor to perform such step.

In addition, each step included in the processing chamber monitoring method performed by the apparatus for monitoring internal conditions of a processing chamber according to the above-described embodiment may be implemented in a computer-readable recording medium on which a computer program containing instructions for prompting a processor to perform such step is recorded.

In the present disclosure, combinations of each step in an attached flowchart may be performed by computer program instructions. Since the computer program instructions may be mounted on a processor of a general-purpose computer, a special-purpose computer, other or programmable data processing equipment, the instructions, executed by a processor in a computer or other programmable data processing equipment, create the means to perform the functions described in each step of the flowchart. The instructions may also be stored on any computer-usable or computer-readable medium that can be directed to a computer or other programmable data processing equipment to implement a function in a particular manner, and thus the instructions stored on the computer-usable or computer-readable recording medium are also capable of producing manufactured articles containing instruction means to perform the functions described in each step of the flowchart. The computer program instructions may also be mounted on a computer or other programmable data processing equipment, and thus the instructions that create a computer-executed process in which a series of operational steps are performed on a computer or other programmable data processing equipment to execute on a computer or other programmable data processing equipment may also provide steps to execute the functions described in each step of the flowchart.

Furthermore, each step may represent a module, segment, or portion of code containing one or more executable instructions to execute specified logical function (s). In addition, it should be noted that in some alternative embodiments it is possible for functions mentioned in steps to occur out of order. For example, it is possible for two steps shown in succession to be performed substantially simultaneously. Alternatively, it is possible for the steps to be performed in reverse order, sometimes depending on the function in question.

The above description is merely illustrative of the technical idea of the present disclosure, and various modifications and variations may be made by those skilled in the art to which the present disclosure pertains without departing from the essential characteristics of the present disclosure. Therefore, the embodiments described in the present disclosure are not intended to limit the technical spirit of the present disclosure, but to explain, and the technical spirit of the present disclosure is not limited by these embodiments. The protection scope of the present disclosure should be construed by the following claims, and all technical ideas within the scope equivalent thereto should be construed as being included in the scope of the present disclosure.

What is claimed is:

1. A system for monitoring internal conditions of a processing chamber, the system comprising:
at least one sensor provided inside the processing chamber and configured to measure an amount of reactants accumulated inside the processing chamber; and
a monitoring apparatus configured to determine at least one of a start point and an end point of a cleaning process for the processing chamber on the basis of a change in the measurement value.

2. The system of claim 1, wherein the at least one sensor is a thin film-type sensor comprising:
a sensing module including a pair of substrates, a pair of electrodes provided between the pair of substrates, and piezoelectric element provided between the pair of electrodes; and
a wireless communication module configured to transmit a measurement value measured by the sensing module to the monitoring apparatus through a wireless communication network.

3. The system of claim 2, wherein the measurement value includes a frequency value for vibration generated by the piezoelectric element, and
the monitoring apparatus monitors the amount of the reactant accumulated inside the processing chamber on the basis of a change in the frequency value.

4. The system of claim 1, wherein the monitoring apparatus determines the start point of the cleaning process on the basis of the measurement value reaching a threshold value.

5. The system of claim 4, wherein the threshold value is set on the basis of at least one of a type of gas discharged inside the processing chamber, a component ratio of the gas, an internal pressure of the processing chamber, and power applied to the processing chamber.

6. The system of claim 1, wherein the monitoring apparatus determines the end point of the cleaning process on the basis of the change in the measurement value within a preset range after the start point of the cleaning process.

7. The system of claim 6, wherein the monitoring apparatus determines the end point of the cleaning process on the basis of the measurement value being within the preset range for a preset period of time after the start point of the cleaning process.

8. The system of claim 1, wherein the at least one sensor includes a plurality of sensors, wherein the plurality of sensors is provided at different locations inside the processing chamber, and
the monitoring apparatus determines the start point of the cleaning process on the basis of whether at least one of measurement values measured by the plurality of sensors is below a preset threshold value, and determines the end point of the cleaning process on the basis of the measurement values measured by the plurality of sensors changing within a preset range.

9. The system of claim 2, wherein the pair of substrates includes at least one of a ceramic material and a polymer-based material, and
the pair of electrodes includes at least one of aluminum, nickel, copper, gold, chromium, titanium, platinum, and tungsten.

10. An apparatus for monitoring internal conditions of a processing chamber, the apparatus comprising:
a communication module configured to receive a measurement value from at least one sensor provided inside the processing chamber; and
a processor configured to monitor the internal conditions of the processing chamber on the basis of the measurement value and to determine at least one of a start point and an end point of a cleaning process for the processing chamber on the basis of a change in the measurement value.

11. The apparatus of claim 10, wherein the measurement value includes a frequency value for vibration generated by a piezoelectric element in the at least one sensor, and
the processor monitors an amount of reactant present inside the processing chamber on the basis of a change in the frequency value.

12. The apparatus of claim 10, wherein the processor determines the start point of the cleaning process on the basis of the measurement value reaching a threshold value.

13. The apparatus of claim 12, wherein the threshold value is set on the basis of at least one of a type of gas discharged inside the processing chamber, a component ratio of the gas, an internal pressure of the processing chamber, and power applied to the processing chamber.

14. The apparatus of claim 10, wherein the processor determines the end point of the cleaning process on the basis of the change in the measurement value within a preset range after the start point of the cleaning process or on the basis of the measurement value being within the preset range for a preset period of time after the start point of the cleaning process.

15. A monitoring method performed by an apparatus that monitors internal conditions of a processing chamber, the method comprising:
receiving a measurement value from at least one sensor provided inside the processing chamber;
monitoring the internal conditions of the processing chamber on the basis of the measurement value; and
determining at least one of a start point and an end point of a cleaning process for the processing chamber on the basis of a change in the measurement value.

16. The method of claim 15, wherein the measurement value includes a frequency value for vibration generated by a piezoelectric element in the at least one sensor, and
the monitoring comprises monitoring an amount of reactant present inside the processing chamber on the basis of a change in the frequency value.

17. The method of claim 15, wherein the determining comprises determining the start point of the cleaning process on the basis of the measurement value reaching a threshold value.

18. The method of claim 17, further comprising:
setting, before the receiving, the threshold value on the basis of at least one of a type of gas discharged inside the processing chamber, a component ratio of the gas, an internal pressure of the processing chamber, and power applied to the processing chamber.

19. The method of claim 15, wherein the determining comprises determining the end point of the cleaning process on the basis of the change in the measurement value within a preset range after the start point of the cleaning process or on the basis of the measurement value being within the preset range for a preset period of time after the start point of the cleaning process.

20. The method of claim 15, further comprising:
outputting at least one of information about the internal conditions of the processing chamber, information about the start point of the cleaning process, and information about the end point of the cleaning process.
